(19) United States
(12) Patent Application Publication
(10) Pub. No.: US 2024/0222319 A1
(43) Pub. Date: Jul. 4, 2024

(54) DEBONDING REPAIR DEVICES

(71) Applicant: ADEIA SEMICONDUCTOR BONDING TECHNOLOGIES INC., San Jose, CA (US)

(72) Inventors: Guilian GAO, Campbell, CA (US); Laura Wills MIRKARIMI, Sunol, CA (US); Gabriel Z. GUEVARA, Gilroy, CA (US); Thomas WORKMAN, San Jose, CA (US); Dominik SUWITO, San Jose, CA (US)

(21) Appl. No.: 18/389,614

(22) Filed: Dec. 19, 2023

Related U.S. Application Data
(60) Provisional application No. 63/477,549, filed on Dec. 28, 2022.

(51) Int. Cl. H01L 23/00

(52) U.S. Cl. CPC H01L 24/98; H01L 24/799; H01L 24/80; H01L 24/05; H01L 2224/05624; H01L 2224/05647; H01L 2224/05655; H01L 2224/8001; H01L 2224/80052; H01L 2224/80357; H01L 2224/80379; H01L 2224/80896; H01L 2924/01006; H01L 2924/04642; H01L 2924/05042; H01L 2924/0544; H01L 2924/059; H01L 2924/0665

(57) ABSTRACT

A method of repairing a bonded structure is disclosed. The method can include debonding from a carrier a first semiconductor element that is bonded to a bonding site of the carrier, cleaning the bonding site of the carrier; and bonding a second semiconductor element to the bonding site of the carrier. The bonding can also include directly bonding the second semiconductor element and the carrier. The method can further include reducing the dielectric bond energy via a surface modification between the first semiconductor element and the carrier. Debonding the bonded structure can include delivering a fluid from one or more nozzles to a bonding interface between the first semiconductor element and the carrier to reduce the bond energy. A temperature adjustment pad can also be included to debond the bonded structure.

### RELATED APPLICATIONS

This application claims the priority benefit of U.S. Provisional Patent Application 63/477,549 filed on Dec. 28, 2022, entitled “DEBONDING REPAIR DEVICES,” which is incorporated by reference herein in its entirety.

### BACKGROUND

### Field

The field relates to methods for debonding semiconductor elements, and, in particular, to debonding element using a debonding repair devise.

### Description of the Related Art

Stacking semiconductor elements, which can be done with direct bonding, can provide many benefits. However, defects can arise when bonding semiconductor elements, such as semiconductor wafers or integrated device dies. There remains a continued need for improved bonded structures.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these implementations are intended to be within the scope of the invention herein disclosed. These and other implementations will become readily apparent to those skilled in the art from the following detailed description of the preferred implementations having reference to the attached figures, the invention not being limited to any particular preferred implementations disclosed.

In one embodiment, a method of repairing a bonded structure can include: debonding from a carrier a first semiconductor element that is directly bonded to a bonding site of the carrier; cleaning the bonding site of the carrier; and bonding a second semiconductor element to the bonding site of the carrier.

In some embodiments, the bonding includes directly bonding the second semiconductor element to the bonding site of the carrier. In some embodiments, the method includes reducing a dielectric bond energy via a surface modification of the first semiconductor element and the carrier.

In some embodiments, the debonding a first semiconductor element from the carrier includes delivering a fluid from one or more nozzles to a bonding interface between the first semiconductor element and the carrier. In some embodiments, delivering the fluid includes delivering the fluid from a vacuum support tool, wherein the vacuum support tool further includes protrusions extending from the vacuum support tool surrounds one or more edges of the first semiconductor element. In some embodiments, the one or more nozzles are disposed within the protrusions.

In some embodiments, the debonding a first semiconductor element from the carrier includes contacting a temperature adjustment pad disposed on a lower surface of a vacuum support tool to a top surface of the first semiconductor element; wherein the temperature adjustment pad applies a thermal shock to the first semiconductor element to weaken the bond between the first semiconductor element and the carrier. In some embodiments, the thermal shock breaks the bond between the first semiconductor element and the carrier.

In some embodiments, the debonding a first semiconductor element from the carrier includes positioning one or more protrusions extending from a vacuum support tool, the one or more protrusions surrounding one or more edges of the first semiconductor element and applying a shear force on the first semiconductor element.

In some embodiments, the method includes etching at least one of an edge of the first semiconductor element and at least a portion of a bonding dielectric layer of the carrier below the etched edge of the first semiconductor element. In some embodiments, the etching includes forming a sloped profile. In some embodiments, the etching includes forming a straight profile.

In some embodiments, the method includes detecting a bonding defect in a bonded structure after bonding the first semiconductor element to the carrier.

In some embodiments, the method includes attaching a vacuum chuck to the carrier and a vacuum support tool to the first semiconductor element.

In some embodiments, the method includes removing the first semiconductor element by applying an upward vacuum force to a top surface of the first semiconductor element.

In another embodiment, a method of repairing a bonded structure can include: cleaning a bonding site of a carrier after a first semiconductor element has been debonded from the bonding site; and bonding a second semiconductor element to the bonding site of the carrier.

In some embodiments, the bonding includes directly bonding the second semiconductor element to the bonding site of the carrier. In some embodiments, the method includes debonding from the carrier the first semiconductor element that is bonded to the bonding site of the carrier. In some embodiments, the method includes reducing a dielectric bond energy via a surface modification of the first semiconductor element and the carrier. In some embodiments, the debonding a first semiconductor element from the carrier includes delivering a fluid from one or more nozzles a bonding interface between the first semiconductor element and the carrier. In some embodiments, delivering the fluid includes delivering the fluid from a vacuum support tool, wherein the vacuum support tool further includes protrusions extending from the vacuum support tool and surrounding one or more edges of the first semiconductor element. In some embodiments, the one or more nozzles are disposed within the protrusions.

In some embodiments, the debonding a defective first semiconductor element from the carrier includes contacting a temperature adjustment pad disposed on a lower surface of a vacuum support tool to a top surface of the first semiconductor element, wherein the temperature adjustment pad applies a thermal shock to the first semiconductor element to weaken the bond between the first semiconductor element and the carrier. In some embodiments, the thermal shock breaks the bond between the first semiconductor element and the carrier.

In some embodiments, the debonding a defective first semiconductor element from the carrier includes positioning one or more protrusions extending from a vacuum support tool that are surrounding one or more edges of the first semiconductor element and applying a shear force on the first semiconductor element.

In some embodiments, the method includes etching at least one of an edge of the first semiconductor element and at least a portion of a bonding dielectric bonding dielectric layer of the carrier below the etched edge of the first semiconductor element. In some embodiments, the etching includes forming a sloped profile. In some embodiments, the etching includes forming a straight profile.

In some embodiments, the method includes detecting a bonding defect in a bonded structure after bonding the first semiconductor element to the carrier.

In some embodiments, the method includes attaching a vacuum chuck to the carrier and a vacuum support tool to the first semiconductor element.

In some embodiments, the method includes removing the first semiconductor element by applying an upward vacuum force to a top surface of the first semiconductor element.

In another embodiment, a method of repairing a bonded structure can include: bonding a first semiconductor element to a carrier at a bonding site of the carrier to form a bonded structure; detecting a bonding defect in the bonded structure after bonding the first semiconductor element to the carrier; debonding the first semiconductor element from the bonding site of the carrier; and bonding a second semiconductor element to the bonding site of the carrier.

In some embodiments, the bonding includes directly bonding the second semiconductor element to the bonding site of the carrier. In some embodiments, the method includes cleaning the bonding site of the carrier after the first semiconductor element has been debonded from the bonding site. In some embodiments, the method includes reducing the dielectric bond energy via a surface modification of the first semiconductor element and the carrier.

In some embodiments, the debonding a first semiconductor element from the carrier includes delivering a fluid from one or more nozzles to a bonding interface between the first semiconductor element and the carrier. In some embodiments, delivering the fluid includes delivering the fluid from in a vacuum support tool, wherein the vacuum support tool further includes protrusions extending from the vacuum support tool and surrounding one or more edges of the first semiconductor element. In some embodiments, the one or more nozzles are disposed within the protrusions.

In some embodiments, the debonding a first semiconductor element from the carrier includes placing a temperature adjustment pad disposed on a lower surface of a vacuum support tool in contact with a top surface of the first semiconductor element, wherein the temperature adjustment pad applies a thermal shock to the first semiconductor element to weaken the bond between the first semiconductor element and the carrier. In some embodiments, the thermal shock breaks the bond between the first semiconductor element and the carrier.

In some embodiments, the debonding a first semiconductor element from the carrier includes positioning one or more protrusions extending from a vacuum support tool, the one or more protrusions surrounding one or more edges of the first semiconductor element and applying a shear force on the first semiconductor element.

In some embodiments, the method includes etching at least one of an edge of the first semiconductor element and at least a portion of a bonding dielectric bonding dielectric layer of the carrier below the etched edge of the first semiconductor element. In some embodiments, the etching includes forming a sloped profile. In some embodiments, the etching includes forming a straight profile.

In some embodiments, the method includes attaching a vacuum chuck to the carrier and a vacuum support tool to the first semiconductor element.

In some embodiments, the method includes removing the first semiconductor element by applying an upward vacuum force to a top surface of the first semiconductor element.

In another embodiment, a method of repairing a bonded structure includes: debonding from a carrier a first semiconductor element that is directly bonded to a bonding site of a carrier; bonding a second semiconductor element to the bonding site of the carrier; and annealing the second semiconductor element and the carrier.

In some embodiments, the bonding includes directly bonding the second semiconductor element and the carrier. In some embodiments, the method includes cleaning the bonding site of the carrier after the first semiconductor element has been debonded from the bonding site. In some embodiments, the method includes reducing a dielectric bond energy via a surface modification of the first semiconductor element and the carrier.

In some embodiments, the debonding a first semiconductor element from the carrier includes delivering a fluid from one or more nozzles a bonding interface between the first semiconductor element and the carrier to reduce the bond energy. In some embodiments, delivering the fluid includes delivering the fluid from a vacuum support tool, wherein the vacuum support tool further includes protrusions extending from the vacuum support tool and surrounding one or more edges of the first semiconductor element. In some embodiments, the nozzles are disposed within the protrusions.

In some embodiments, the debonding a first semiconductor element from the carrier includes placing a temperature adjustment pad disposed on a lower surface of a vacuum support tool in contact with a top surface of the first semiconductor element, wherein the temperature adjustment pad applies a thermal shock to the first semiconductor element to weaken the bond between the first semiconductor element and the carrier. In some embodiments, the thermal shock breaks the bond between the first semiconductor element and the carrier.

In some embodiments, the debonding a first semiconductor element from the carrier includes positioning one or more protrusions extending from a vacuum support tool, the one or more protrusions surrounding one or more edges of the first semiconductor element and applying a shear force on the first semiconductor element.

In some embodiments, the method includes etching at least one of an edge of the first semiconductor element and at least a portion of a bonding dielectric bonding dielectric layer of the carrier below the etched edge of the first semiconductor element. In some embodiments, the etching includes sloped profile. In some embodiments, the etching includes a straight profile.

In some embodiments, the method includes detecting a bonding defect in a bonded structure after a bonding of a first semiconductor element and a carrier.

In some embodiments, the method includes attaching a vacuum chuck to the carrier and a vacuum support tool to the first semiconductor element.

In some embodiments, the method includes removing the first semiconductor element by applying an upward vacuum force to a top surface of the first semiconductor element.

In another embodiment, a debonding repair device can include: a vacuum chuck configured to temporarily attach to a carrier of an in-process bonded structure; a vacuum support tool configured to attach to a first semiconductor element of the in-process bonded structure, the vacuum support tool extending to a periphery of the first semiconductor element, the vacuum support tool includes one or more vacuum channels configured to produce an upward force on the first semiconductor element; and a fluid spraying system includes one or more nozzles for dispensing the fluid at an interface between the carrier and the first semiconductor element.

In some embodiments, the vacuum support tool lifts the first semiconductor element after a bonding interface between the carrier and the first semiconductor element is weakened. In some embodiments, the bonding interface between the carrier and the first semiconductor element is broken.

In some embodiments, the one or more vacuum channels of the vacuum support tool are disposed at the periphery of the vacuum support tool. In some embodiments, the vacuum support tool includes protrusions extending from the vacuum support tool and configured to surround the first semiconductor element. In some embodiments, the one or more nozzles are disposed within the vacuum support tool. In some embodiments, the one or more nozzles are disposed within the protrusions.

In some embodiments, the debonding repair device includes an enclosure surrounding the first semiconductor element and the vacuum support tool. In some embodiments, the enclosure removes a dispensed fluid. In some embodiments, the enclosure includes a vacuum port to remove the dispensed fluid.

In some embodiments, the debonding repair device includes a jet impingement configured to dispense the fluid. In some embodiments, the fluid is at least one of a gas or a liquid. In some embodiments, the gas is at least one of an oxidizing gas, a reducing gas, and an inert gas. In some embodiments, the gas is steam. In some embodiments, the steam is from a de-oxygenated water source transported in an inert carrier gas to minimize oxidation of any exposed metallization. In some embodiments, the fluid spraying system includes a heater to warm the fluid.

In some embodiments, the debonding repair device includes a processor and one or more sensors configured to control and monitor the vacuum support tool. In some embodiments, the processors and one or more sensors measure at least one of temperature, pressure, and flow rate of the fluid. In some embodiments, the processor and one or more sensors control the amount of time the fluid is dispersed.

In another embodiment, a debonding repair device can include: a vacuum chuck configured support a carrier of a bonded structure; a vacuum support tool configured to support a first semiconductor element of the bonded structure, the vacuum support tool extending to a periphery of the first semiconductor element, the vacuum support tool includes one or more vacuum channels to produce an upward force on the first semiconductor element to separate the first semiconductor element from the carrier; and a temperature adjustment pad disposed on a lower surface of the vacuum support tool, the temperature adjustment pad is configured to contact the first semiconductor element and apply a thermal shock to the first semiconductor element to weaken the bond of the first semiconductor element and the carrier.

In some embodiments, the thermal shock breaks the bond between the first semiconductor element and the carrier. In some embodiments, temperature adjustment pad applies a hot thermal shock. In some embodiments, the temperature adjustment pad is at a constant temperature between 150 to 200 degrees Celsius. In some embodiments, the temperature adjustment pad applies a cold thermal shock. In some embodiments, the temperature adjustment pad is at a constant temperature of −20 degrees Celsius.

In some embodiments, the debonding repair device includes an enclosure surrounding the first semiconductor element and vacuum support tool. In some embodiments, the enclosure is configured to dispense a flow of an inert gas into the enclosure to remove air from a volume surrounding the first semiconductor element to prevent condensation if the temperature adjustment pad is colder than a dew point of an ambient environment of the debonding repair device.

In some embodiments, the debonding repair device includes a processor and one or more sensors configured to control and monitor the vacuum support tool. In some embodiments, the processor and the one or more sensors are configured to control and monitor a temperature of the temperature adjustment pad.

In another embodiment, a debonding repair device can include: a vacuum chuck configured to temporarily attach to a carrier of a bonded structure; and a vacuum support tool extending to a periphery of a first semiconductor element and configured to temporarily attach to a first semiconductor element of the bonded structure includes: one or more vacuum channels to produce an upward force on the first semiconductor element to separate the first semiconductor element from the carrier; and one or more protrusions extending from the vacuum support tool, the one or more protrusions are configured to surround one or more edges of the first semiconductor element and applying a shear force on the first semiconductor element.

In some embodiments, the vacuum support tool includes at least two protrusions. In some embodiments, the vacuum support tool includes at least four protrusions. In some embodiments, the shear force includes a rotational force to break a bond interface between the carrier and the first semiconductor element. In some embodiments, the protrusions include substantially straight sidewalls configured to be pressed against one or more sides of the first semiconductor element to apply the rotational force. In some embodiments, the protrusions include an actuator configured to spread the protrusions wider than the first semiconductor element during an initial positioning of the vacuum support tool and then close the protrusions along the sides of the first semiconductor element before applying the rotational force. In some embodiments, the rotational force includes a translation force on an edge of the first semiconductor element. In some embodiments, the protrusions include substantially straight sidewalls configured to be pressed against one or more sides of the first semiconductor element to apply the translation force. In some embodiments, the protrusions include an actuator configured to spread the protrusions wider than the first semiconductor element during an initial positioning of the vacuum support tool and then close the protrusions along the sides of the first semiconductor element before applying the translation force. In some embodiments, the debonding repair device includes a shaft/mechanism configured to apply at least one of the rotational force and the translation force.

In some embodiments, the vacuum support tool applies an upward vacuum force. In some embodiments, the protrusions are parallel to one or more edges of the first semiconductor element. In some embodiments, the protrusions create a pocket underneath a lower surface the vacuum support tool. In some embodiments, the pocket is 0.1 mm to 1.0 mm larger than the first semiconductor element. In some embodiments, the protrusions include a height that is shorter than a thickness of a first semiconductor element by an amount large enough to prevent the protrusions from contacting the carrier. In some embodiments, the amount to prevent the protrusions from contacting the carrier is between 25 μm to 50 μm. In some embodiments, the debonding repair device includes a processor and one or more sensors configured to control and monitor the vacuum support tool. In some embodiments, the processor and one or more sensors monitor and control at least a distance of the shear force, an angular rotation of the shear force, and a total amount of force of the shear force.

In another embodiment, a debonding repair device can include: a vacuum chuck configured to temporarily attach to a carrier of a bonded structure; a vacuum support tool including a vacuum support tool, the vacuum support tool configured to attach to a first semiconductor element of the bonded structure, the vacuum support tool extending to a periphery of the first semiconductor element, the vacuum support tool includes one or more vacuum channels to produce an upward force on the first semiconductor element to separate the first semiconductor element from the carrier; a fluid spraying system includes one or more nozzles for dispensing the fluid at an interface between the carrier and the first semiconductor element; a temperature adjustment pad disposed on a lower surface of the vacuum support tool, the temperature adjustment pad configured to contact the first semiconductor element; one or more protrusions extending from the vacuum support tool and configured to surround one or more edges of the first semiconductor element and configured to apply a shear force on the first semiconductor element; and a processor and one or more sensors configured to control and monitor the vacuum support tool.

In some embodiment, the debonding repair device includes any of the features mentioned above.

### BRIEF DESCRIPTION OF THE DRAWINGS

Various implementations will be described hereinafter with reference to the accompanying drawings. These implementations are illustrated and described by example only and are not intended to limit the scope of the disclosure. In the drawings, similar elements have similar reference numerals.

FIG. 1A is a schematic cross-sectional side view of a debonding repair device, according to various embodiments.

FIG. 1B is a schematic cross-sectional side view of a debonding repair device removing a semiconductor element.

FIG. 1C is a schematic cross-sectional side view of a semiconductor element bonded to a carrier following the removal of a semiconductor element.

FIG. 2 is a perspective view of an enclosure surrounding the debonding repair device of FIG. 1A.

FIG. 3 is a schematic cross-sectional side view of another embodiment of a debonding repair device.

FIG. 4 is a perspective view of an enclosure surrounding the debonding repair device of FIG. 3.

FIG. 5 is a schematic cross-sectional side view of another embodiment of a debonding repair device.

FIG. 6 is a perspective view of an enclosure surrounding another embodiment of a debonding repair device.

FIG. 7 is a schematic cross-sectional side view of two examples illustrating etching at least one edge of a bonded structure.

FIGS. 8A-8B schematically illustrate a process for forming a directly hybrid bonded structure without an intervening adhesive according to some embodiments.

### DETAILED DESCRIPTION

### Overview

The present disclosure may be understood by reference to the following detailed description. It is noted that, for purposes of illustrative clarity, certain elements in various drawings may not be drawn to scale, may be represented schematically or conceptually, or otherwise may not correspond exactly to certain physical configurations of embodiments.

Various embodiments disclosed herein relate to debonding directly bonded structures to remedy a defect formed during the bonding process. A first semiconductor element (e.g., a die, wafer, etc.) can be directly bonded to a carrier (e.g., a die, wafer, etc.) without an adhesive. A full carrier (e.g., wafer) imaging process can be conducted of the entire carrier (e.g., wafer) during the bonding phase and/or as soon as the dielectric bonding is completed in order to identify any defects in the bonded structures. Once the imaging is completed, the defective bonded structure can be debonded by a debonding repair device. In various embodiments herein, the debonding step can be performed on a bonded structure in which only nonconductive materials (e.g., insulators such as dielectric materials) are directly bonded and in which opposing conductive contact features (if any) are not directly bonded (or have not yet been directly bonded). For example, the debonding step may be performed before an annealing step in a hybrid direct bonding process is performed to form direct conductor-to-conductor bonds. Alternatively, the debonding step may be performed on bonded structures in which only insulating materials are directly bonded. Before the bonding interface becomes too strong for separation, the debonding repair device can be used to weaken the dielectric bond in order to remove a semiconductor element from a carrier. It can be important to weaken the bond such that removal of the semiconductor device does not damage either the semiconductor device or the carrier. After the first semiconductor element is debonded from the bonding site of the carrier, the bonding site can be inspected and cleaned, and a second semiconductor element can then be directly bonded to the bonding site of the carrier (e.g., to the same bonding site from the first semiconductor element was debonded or removed). The second semiconductor element and carrier can be annealed to form a stronger dielectric bond and/or a hybrid direct bond which includes nonconductive-nonconductive direct bonds and conductor-conductor direct bonds, such as DBI® bonding, techniques commercially available from Adeia of San Jose, CA.

### Example Embodiments of Debonding Repair Devices

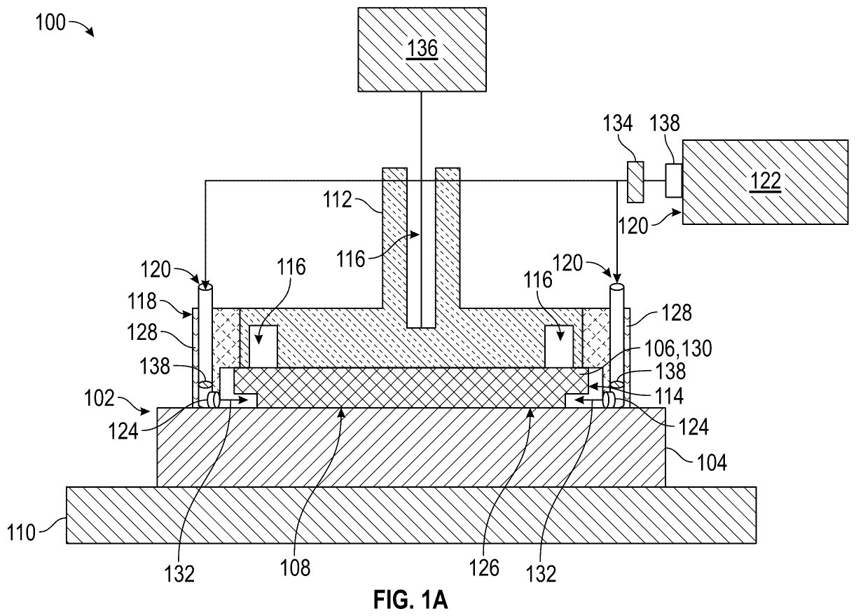

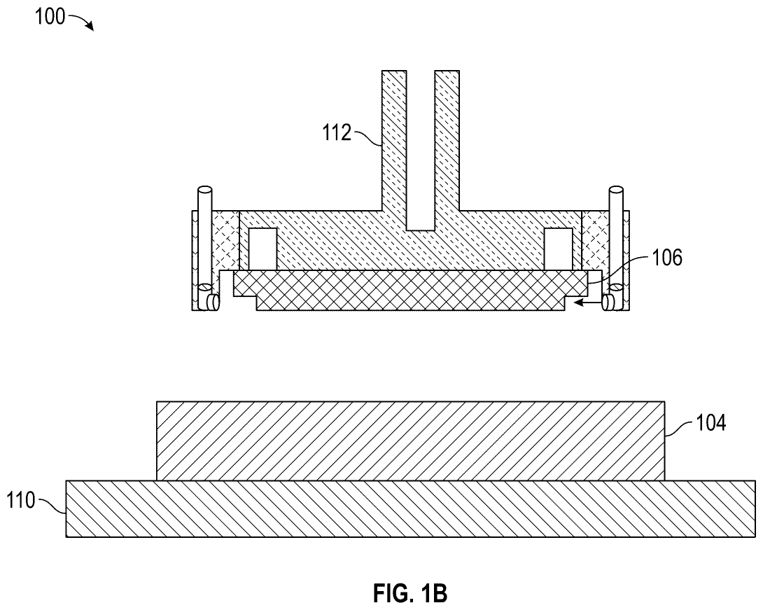

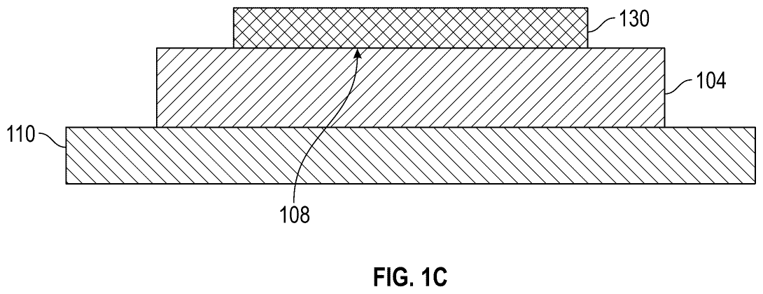

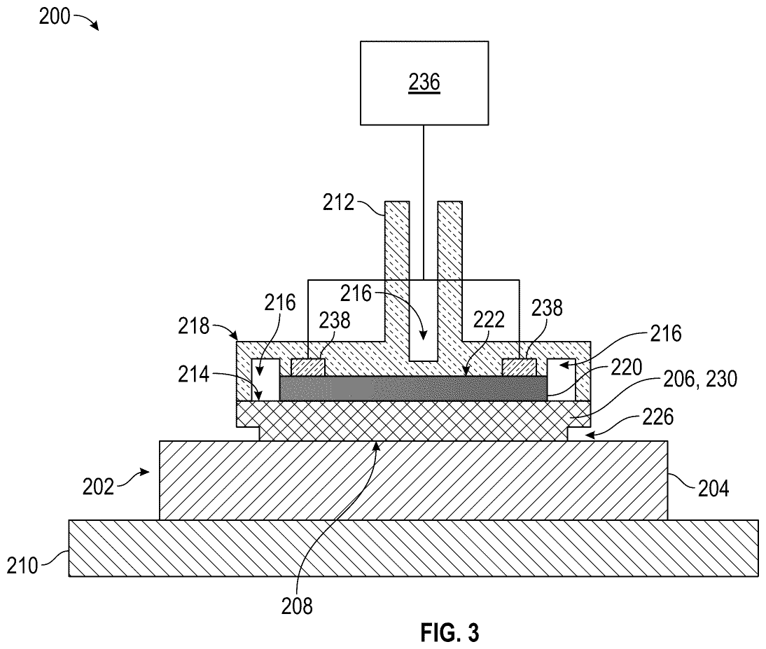

FIG. 1A illustrates a debonding repair device 100 used in a repairing process of a bonded structure 102 to debond a first semiconductor element 106 from a carrier 104 that is directly bonded using non-conductive direct bonds (e.g., only non-conductive bonds) to a bonding site 108 of the carrier 104. The debonding repair device 100 can include a vacuum chuck 110 that temporarily attaches to the carrier 104 of the bonded structure 102 and a vacuum support tool 112 that attaches to the first semiconductor element 106. The vacuum support tool 112 can extend to a periphery 114 of the first semiconductor element 106 and include one or more vacuum channels 116 to produce an upward force on the first semiconductor element 106. In some embodiments, the one or more vacuum channels 116 can be located at the periphery 118 of the vacuum support tool 112. The vacuum support tool 112 can also include a fluid spraying system 120 having a storage source 122 and one or more nozzles 124 for dispensing a fluid at a bonding interface 126 between the carrier 104 and the first semiconductor element 106. The fluid system 120 can be incorporated into the vacuum support tool 112 or be applied by a standalone system. The fluid system 120 can provide a surface modification to reduce the dielectric bond energy between the carrier 104 and the first semiconductor element 106. The vacuum support tool 112 can further include protrusions 128 extending from the vacuum support tool 112 such that the protrusions 128 surround (or partially surround) the first semiconductor element 106. The nozzles 124 can be positioned within the vacuum support tool 112, for example, within the protrusions 128. The vacuum support tool 112 can then lift the first semiconductor element 106 off of the carrier 104 after the bonding interface 126 between the carrier 104 and the first semiconductor element 106 is debonded by the upward force and fluid dispersion. FIG. 1B illustrates the removal of the first semiconductor element 106 from the carrier 104. Following the removal of the first semiconductor element 106, the bonding site 108 can be cleaned and cleared of any debris, and a second semiconductor element 130 can be attached to the carrier 104 at the bonding site 108 as illustrated in FIG. 3.

In some embodiments, a jet impingement 132 (e.g., water, steam, and/or air jet knife) can be applied as a method used to dispense the fluid at the bond interface 126 to remove (e.g., “unzip”) the dielectric bond formed and/or forming between the carrier 104 and the first semiconductor element 106. The fluid dispensed by the fluid system 120 can be at least one of a gas or a liquid. In some embodiments, the gas is at least one of an oxidizing gas, a reducing gas, and an inert gas. The gas can also be dispersed in the form of a steam. The steam can be from a de-oxygenated water source transported in an inert carrier gas to reduce or minimize oxidation of any exposed metallization. In some embodiments, a heater 134 can be used to warm the fluid before the fluid is dispensed at the bonding interface 126, which may improve the debonding efficacy.

The debonding repair device can also include a processor 136 and one or more sensors 138 to control and monitor the vacuum support tool 112. The sensors 138 can measure the temperature, pressure, and/or flow rate of the fluid 132 associated with repairing the bonded structure 102 to monitor and control the debonding repair device 100. In some embodiment, the processor 136 and the one or more sensors 138 control the amount, timing, velocity, and/or other similar characteristics of the dispersed fluid 132. In some embodiments, the processor 136 and the one or more sensors 138 can also control the vacuum flow from vacuum channels 116 to attach to the first semiconductor element 106. The sensors 138 can be located at the protrusions 128 such as at the nozzles 124. In some embodiments, the sensors 138 can be positioned on or along the vacuum support tool 112 to measure the amount of force being applied to the bonded structure 102 to prevent any damage to the bonded structure 102.

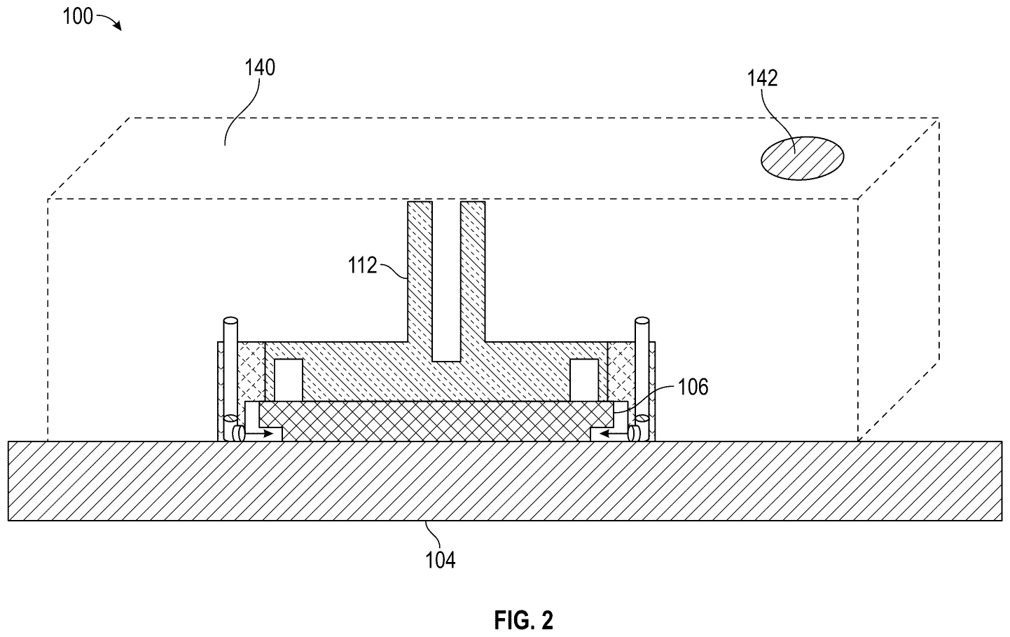

As shown in FIG. 2, in some embodiments, the debonding repair device 100 can further include an enclosure 140 that can be pressed to a surface of carrier 104 and surrounds and forms a seal around at least one of the first semiconductor element 106, the vacuum support tool 112, and the fluid system 120. In some embodiments, the enclosure 140 can remove dispensed fluid within the enclosure 140 via a vacuum port 142 located on a surface of the enclosure 140. Additionally or alternatively, the enclosure 140 can protect other adjacent semiconductor elements from being affected by the fluid and/or fluid system 120.

To assist in the debonding process at the bonding interface, one more methods, such as the jet impingement mentioned above, can be employed in conjunction with the debonding repair device. At the bonding interface during bond propagation, both exposed surfaces of the first semiconductor element and carrier forming the bonding interface can be lined with layer(s) of water molecules. Before and after bonding, gaps at the bond interface are filled with water which eventually stabilizes. Without being limited by theory, in various embodiments, direct bonding may be conceptually separated into two stages. In stage one, hydrogen bonding can occur upon contact of the layers of water. In stage two, covalent bonds can form (e.g., upon annealing) along with condensation of water molecules. The bonding energy can slowly increase. Although the reaction is reversible, it becomes harder to separate the bonding interface due to bonding energy increase as time progresses. The bonding energy may also increase rapidly when the bonded structure is exposed to higher temperatures.

One approach to aid in the debonding process is to reduce or minimize the initial bonding energy level which requires balancing the high bonding energy requirement after annealing the bonded structure and the low initial bonding energy. Before bonding the bonded structure, water absorption can be reduced or minimized by heat drying the carrier and/or the semiconductor element to reduce the water content on either surface. Additionally or alternatively, a jet impingement (e.g., hot air knife) can be implemented to remove moisture at the bonding interface and/or a water jet knife can also be used to reverse the condensation process. Increasing the dielectric surface roughness or patterning recesses in the dielectric can also be used to reduce initial bond energy. Another method for reducing or minimizing bonding energy involves performing activation process(es) that are not designed for high bond energy (e.g., using O₂ plasma activation instead of N₂ plasma activation, selected plasma parameters that result in lower bond energy, non-plasma activation (e.g., a wet dip activation, etc.). Further incorporating volatile species of very small molecules that can explode with high heating power shortly after bonding for removal but can diffuse away the bonding interface if heated slowly can be included along a bonding layer. Coating the semiconductor element with a temporary coating with a higher coefficient of thermal expansion (CTE) material to warp the semiconductor element can assist when applying a thermal shock to remove the semiconductor element. Surface engineering can also be utilized to control the density of water absorption sites by introducing atomic layer deposition of certain species and/or a wet chemical termination process. Additionally or alternatively, the water can be replaced with low surface tension solvents as a final rinse before the direct bonding process.

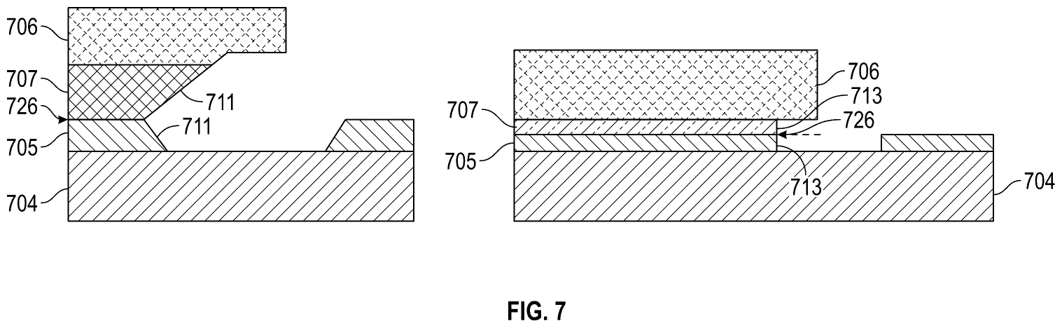

As illustrated in FIG. 7, an engineered opening (e.g., etching) at the edge of the first semiconductor element 706 corresponding position on the carrier 704 can assist in the insertion of the gas or jet impingement 132 in weakening the dielectric bond between the first semiconductor element 706 and the carrier 704. For example, in FIG. 7, the bonding dielectric layer 707 of the first semiconductor element 706 and/or a small portion of the first semiconductor element 706 are etched off at the edge of the first semiconductor element 706, and the bonding dielectric layer 705 of the carrier 704 below the etched edge of the first semiconductor element 706 is also etched off. A sloped profile 711 or straight wall 713 can be engineered to improve the debonding process. Additionally or alternatively, the etching the first semiconductor element 706 and the carrier 704 can remove obstacles preventing the gas or jet impingement 132 from reaching the bond interface 726. In some embodiments, the etching can be done on one side of the bonding interface 726 only (e.g., only the edge of the bonding dielectric layer 707 of the first semiconductor element 706 is etched or at least a portion of the bonding dielectric layer 705 of the carrier 704 beneath the edge of the first semiconductor element 706 is etched).

FIG. 3 illustrates another embodiment of a debonding repair device 200. The debonding repair device 200 can include a substrate or wafer support (e.g., a vacuum chuck 210) that temporarily attaches to the carrier 204 of the bonded structure 202 and a vacuum support tool 212 that attaches to a first semiconductor element 206 positioned on a bonding site 208 on the carrier 204. The vacuum support tool 212 can extend to a periphery 214 of the first semiconductor element 206 and include one or more vacuum channels 216 to produce an upward force on the first semiconductor element 206. In some embodiments, the one or more vacuum channels 216 can be located at the periphery 218 of the vacuum support tool 212. The vacuum support tool 212 can further include a temperature adjustment pad 220 located on a lower surface 222 of the vacuum support tool 212. The temperature adjustment pad 220 can contact the first semiconductor element 206 to apply a thermal shock (e.g., a constant thermal shock) to weaken the bond energy between the carrier 204 and the first semiconductor element 206. In some embodiments, the thermal shock can break the bond between the carrier 204 and the first semiconductor element 206. Additionally or alternatively, the temperature adjustment pad 220 can quickly cycle between different temperatures until a target temperature is reached. In some embodiments, the temperature adjustment pad 220 can apply a hot thermal shock to the first semiconductor 206, for example, in a range between 50° C. to 300° C., in a range between 75° C. to 275° C., in a range between 100° C. to 250° C., in a range between 125° C. to 225° C., or in a range between 150° C. to 200° C. In some embodiments, the temperature adjustment pad 220 can apply a cold thermal shock being less than 20° C., less than 10° ° C., less than 0° C., less than −10° C., or less than −20° C. In some embodiments, the temperature adjustment pad 220 can use liquid nitrogen (LN₂) to apply the cold thermal shock. The hot shock and/or cold shock can be held at a constant temperature by the temperature adjustment pad 220. The vacuum support tool 212 can then lift the first semiconductor element 206 off of the carrier 204 after the bonding interface 226 between the carrier 204 and the first semiconductor element 206 is debonded by the upward force and thermal shock. Following the removal of the first semiconductor element 206, as shown in FIGS. 1B-1C, the bonding site 208 can be cleaned and cleared of any debris, and a second semiconductor element 230 can be attached to the carrier 204 at the bonding site 208.

The debonding repair device 200 can also include a controller 236 (including one or more processors) and one or more sensors 238 to control and monitor the vacuum support tool 212. The sensors 238 can measure the temperature, pressure, and/or rate of temperate change of the temperature adjustment pad 220 and/or bonded structure 202 to monitor and control the debonding repair device 200. In some embodiment, the processor 236 and one or more sensors 238 control the amount, timing, rate, and/or other similar characteristics of the temperature adjustment pad 220. The sensors 238 can be located on the vacuum support tool 212 and/or along the temperature adjustment pad 220. In some embodiments, the sensors 238 positioned on the vacuum support tool 212 can measure the amount of force being applied to the bonded structure 202 to prevent any damage to the bonded structure.

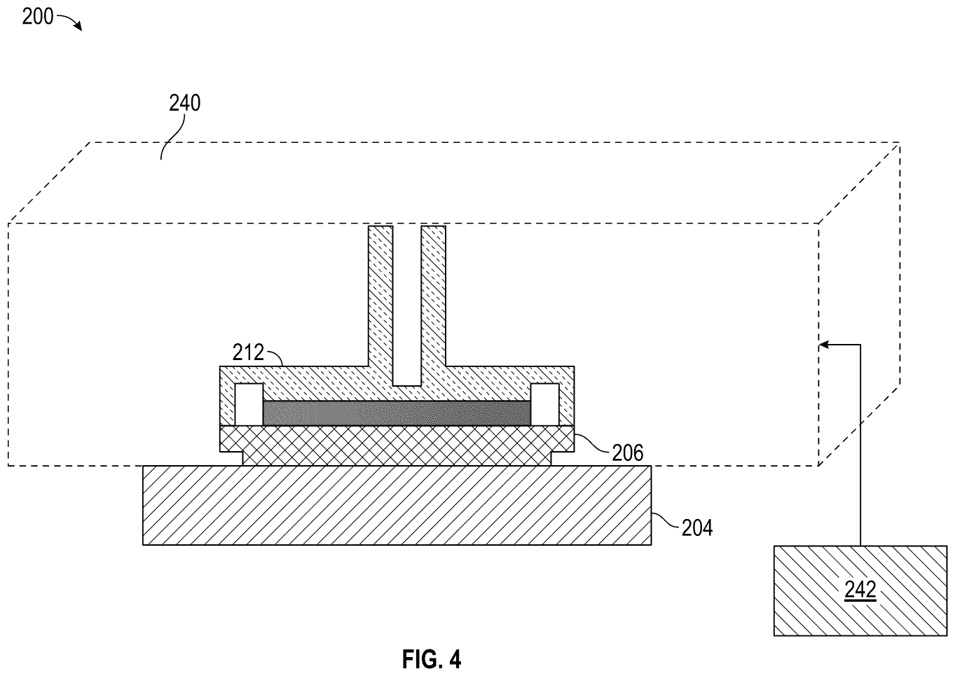

As shown in FIG. 4, the debonding repair device 200 can further include an enclosure 240 that can be pressed to a surface of carrier 204 and surrounds and forms a scale around at least one of the bonded structure 202 and the debonding repair device 200, particularly the first semiconductor element 206 and the vacuum support tool 212. An inert gas stored in in storage tank 242 can be dispensed into the enclosure 240 to remove air from the volume surrounding the first semiconductor element 206 to prevent condensation if the temperature adjustment pad 220 is colder than a dew point of an ambient environment of the debonding repair device 200.

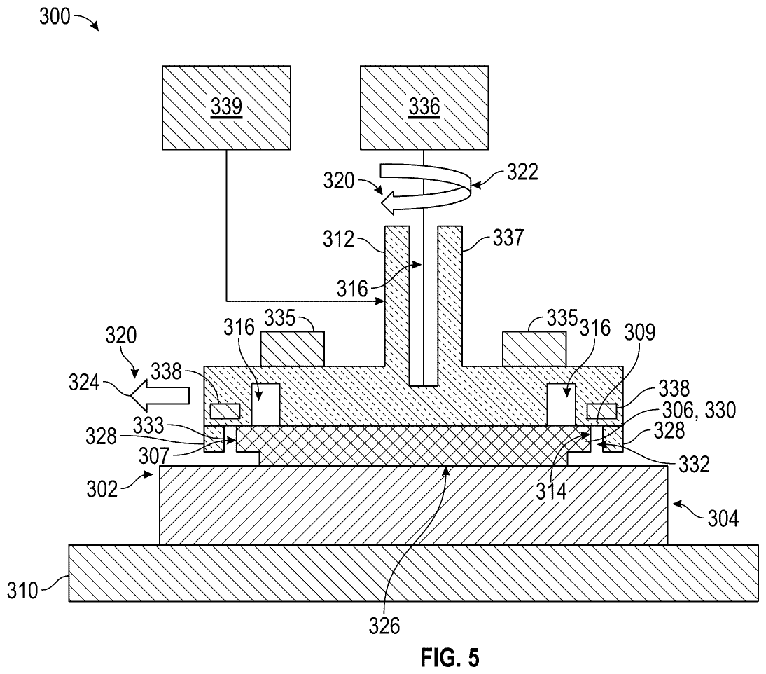

FIG. 5 illustrates another embodiment of a debonding repair device 300 used in a repairing process of a bonded structure 302 to debond a first semiconductor element 306 that is directly bonded to a bonding site 308 of the carrier 304. The debonding repair device 300 can include a vacuum chuck 310 that temporarily attaches to the carrier 304 of the bonded structure 302 and a vacuum support tool 312 that attaches to the first semiconductor element 304. The vacuum support tool 312 can extend to a periphery 314 of the first semiconductor element 306 and include one or more vacuum channels 316 to produce an upward force on the first semiconductor element 306 to separate the first semiconductor element 306 from the carrier 304. The vacuum support tool 312 can also include one or more protrusions 328, for example, 2, 3, 4, 5, 6, 7, 8, and so on, extending from the vacuum support tool 312 to surround one or more edges 307 of the first semiconductor element 306 and to apply a shear force 320 on the first semiconductor element 306. In some embodiments, the protrusions 328 can be parallel to the one or more edges 307 of the first semiconductor element 306. The protrusions 328 can also create a pocket 332 underneath a lower surface 309 of the of the vacuum support tool 312. The pocket 332 can have a width of 0.1 mm to 3.0 mm, 0.1 mm to 2.0 mm, or 0.1 mm to 1.0 mm larger than the first semiconductor element 306. In some embodiments, the protrusions 328 can have a height that is shorter than a thickness of a first semiconductor element 306 by an amount large enough to prevent the protrusions 328 from contacting the carrier 304 such as between 10 μm to 75 μm, between 15 μm and 60 μm, between 20 μm and 55 μm, or between 25 μm and 50 μm.

The shear force 320 can be either a rotational force 322, a translation force 324, or a combination of both 322, 324 such that the shear force 320 disrupts the bond interface 326 between the carrier 304 and the first semiconductor element 306. The translation force 324 can be applied on a longer edge of the first semiconductor element 306 to efficiently distribute the force. In some embodiments, the protrusions 328 have substantially straight sidewalls 333 that are pressed against one or more edges 307 of the first semiconductor element 306 to apply the shear force 320. The vacuum support tool 312 can also include an actuator 335 connected to the protrusions 328 that spreads the protrusions 328 wider than the first semiconductor element 306 during an initial positioning of the vacuum support tool 312 and then close the protrusions 328 along the sides 307 of the first semiconductor element 306 before applying the shear force 320 (e.g., rotational force 322 and/or translation force 324). A shaft and/or drivetrain 337 to transfer the rotational force 322 and/or translation force 324 from a source 339 (e.g., motor) can be connected to the debonding repair device 300 in order to provide the shear force 320. The vacuum support tool 312 can then lift the first semiconductor element 306 off of the carrier 304 after the bonding interface 326 between the carrier 304 and the first semiconductor element 306 is debonded by the upward force and fluid dispersion. Following the removal of the first semiconductor element 306, the bonding site 308 can be cleaned and cleared of any debris, and a second semiconductor element 330 can be attached to the carrier 304 at the bonding site 308.

The debonding repair device 300 can further include a processor 336 and one or more sensors 338 to control and/or monitor the vacuum support tool 312. The sensors 338 can measure the distance and/or amount of the shear force, an angular rotation of the shear force, pressure, and/or a total of force being applied to the bonded structure 302 to monitor and/or control the debonding repair device 300. In some embodiment, the processor 336 and one or more sensors 338 control the amount, timing, rate, and/or other similar characteristics of the debonding repair device 300. The sensors 338 can be located at the protrusions 328 and/or along the vacuum support tool 312. In some embodiments, the sensors 338 can be positioned on the vacuum support tool 312 to measure the amount of force being applied to the bonded structure 302 to prevent any damage to the bonded structure 302.

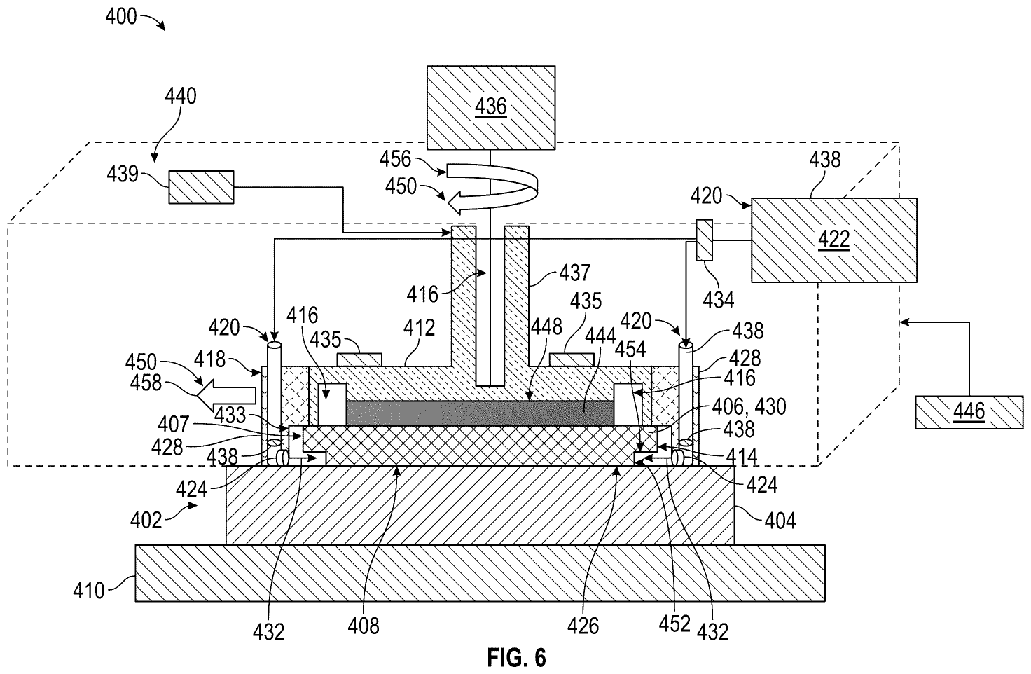

FIG. 6 illustrates another embodiment of a debonding repair device 400. The debonding repair device 400 can be generally similar to the embodiments of FIGS. 1A-5. Unlike the embodiments of FIGS. 1A-5, the debonding repair device 400 can include combinations of the features and methods mentioned in the preceding sections. The debonding repair device 400 can be used in a repairing process of a bonded structure 402 to debond a carrier 404 from a first semiconductor element 406 that is directly bonded to a bonding site 408 of the carrier 404. The debonding repair device 400 can include a vacuum chuck 410 that temporarily attaches to the carrier 404 of the bonded structure 402 and a vacuum support tool 412 that attaches to the first semiconductor element 406. The vacuum support tool 412 can extend to a periphery 414 of the first semiconductor element 406 and include one or more vacuum channels 416 to produce an upward force on the first semiconductor element 406. In some embodiments, the one or more vacuum channels 416 can be located at the periphery 418 of the vacuum support tool 412. The vacuum support tool 412 can also include a fluid spraying system 420 having a storage source 422 one or more nozzles 424 for dispensing a fluid at a bonding interface 426 between the carrier 404 and the first semiconductor element 406. The fluid system 420 can be incorporated into the vacuum support tool 412 or be applied by standalone system. The fluid system 420 can provide a surface modification to reduce the dielectric bond energy between the carrier 404 and the first semiconductor element 406. The vacuum support tool 412 can further include protrusions 428 extending from the vacuum support tool 412 such that the protrusions 428 surround the first semiconductor element 406. The nozzles 424 can be positioned within the vacuum support tool 412, for example, within the protrusions 428.

The vacuum support tool 412 can further include a temperature adjustment pad 444 located on a lower surface 448 of the vacuum support tool 412. The temperature adjustment pad 444 can contact the first semiconductor element 406 to apply a thermal shock to weaken the bond energy between the carrier 404 and the first semiconductor element 406. In some embodiments, the thermal shock can break the bond between the carrier 404 and the first semiconductor element 406. Additionally or alternatively, the temperature adjustment pad 444 can quickly cycle between different temperatures until a target temperature is reached. In some embodiments, the temperature adjustment pad 444 can apply a hot thermal shock to the first semiconductor 406, for example, in a range between 50° C. to 300° ° C., in a range between 75° C. to 275° C., in a range between 100° C. to 250° C., in a range between 125° C. to 225° C., or in a range between 150° C. to 200° C. In some embodiments, the temperature adjustment pad 444 can apply a cold thermal shock being less than 20° C., less than 10° C., less than 0° C., less than −10° C., or less than −20° C. In some embodiments, the hot shock and/or cold shock can be held at a constant temperature by the temperature adjustment pad 444.

The vacuum support tool 412 can also include one or more protrusions 428, for example, 2, 3, 4, 5, 6, 7, 8, and so on, extending from the vacuum support tool 412 to surround one or more edges 407 of the first semiconductor element 406 and to apply a shear force 450 on the first semiconductor element 406. In some embodiments, the protrusions 428 can be parallel to the one or more edges 407 of the first semiconductor element 406. The protrusions 428 can also create a pocket 452 underneath a lower surface 454 of the first semiconductor element 406 opposite of the vacuum support tool 412. The pocket 454 can be 0.1 mm to 3.0 mm, 0.1 mm to 2.0 mm, or 0.1 mm to 1.0 mm larger than the first semiconductor element 306. In some embodiments, the protrusions 428 can be a height that is shorter than a thickness of a first semiconductor element 406 by an amount large enough to prevent the protrusions 428 from contacting the carrier 404 such as between 10 μm to 75 μm, between 15 μm and 60 μm, between 20 μm and 55 μm, or between 25 μm and 50 μm.

The shear force 450 can be either a rotational force 456, a translation force 458, or a combination of both the rotational force 456 and the translational force 458 such that the shear force 420 disrupts the bond interface 426 between the carrier 404 and the first semiconductor element 306. In some embodiments, the protrusions 428 have substantially straight sidewalls 433 that are pressed against one or more edges 407 of the first semiconductor element 406 to apply the shear force 450. The vacuum support tool 412 can also include an actuator 435 connected to the protrusions 428 that spreads the protrusions 428 wider than the first semiconductor element 406 during an initial positioning of the vacuum support tool 412 and then close the protrusions 428 along the sides 407 of the first semiconductor element 306 before applying the shear force 450 (e.g., rotational force 456 and/or translation force 458). A shaft and/or drivetrain 437 to transfer the rotational force 322 and/or translation force 324 from a source 439 (e.g., motor) can be connected to the debonding repair device 400 in order to provide the shear force 450.

The vacuum support tool 412 can then lift the first semiconductor element 406 off of the carrier 404 after the bonding interface 426 between the carrier 404 and the first semiconductor element 406 is debonded by the upward force by any of the methods mentioned above. Following the removal of the first semiconductor element 406, the bonding site 408 can be cleaned and cleared of any debris, and a second semiconductor element 430 can be attached to the carrier 404 at the bonding site 408.

In some embodiments, a jet impingement 432 (e.g., water, steam, and/or air jet knife) can be applied as a method used to dispense the fluid at the bond interface 426 to unzip the dielectric bond formed and/or forming between the carrier 404 and the first semiconductor element 106. The fluid dispensed by the fluid system 420 can be at least one of a gas or a liquid. In some embodiments, the gas is at least one of an oxidizing gas, a reducing gas, and an inert gas. The gas can also be dispersed in the form of a steam. The steam can be from a de-oxygenated water source transported in an inert carrier gas to minimize oxidation of any exposed metallization. A heater 434 can be used to warm the fluid before the fluid is dispensed at the bonding interface.

The debonding repair device can also include a processor 436 and one or more sensors 438 to control and monitor the vacuum support tool 412. The sensors 438 can measure the temperature, pressure, and/or flow rate of the fluid 432 associated with repairing the bonded structure 402 to monitor and control the debonding repair device 400. In some embodiment, the processor 436 and the one or more sensors 438 control the amount, timing, velocity, and/or other similar characteristics of the dispersed fluid 432. The sensors 438 can be located at the protrusions 428 such as at the nozzles 424. In some embodiments, the sensors 438 can measure the temperature, pressure, and/or rate of temperate change of the temperature adjustment pad 444 and/or bonded structure 402 to monitor and control the debonding repair device 400. Additionally or alternatively, the processor 436 and one or more sensors 438 control the amount, timing, rate, and/or other similar characteristics of the temperature adjustment pad 444. The sensors 438 can be located on the vacuum support tool 412 and/or along the temperature adjustment pad 444. In some embodiments, the sensors 438 can measure the distance and/or amount of the shear force, an angular rotation of the shear force, pressure, and/or a total of force being applied to the bonded structure 402 to monitor and/or control the debonding repair device 400. In some embodiment, the processor 436 and one or more sensors 438 control the amount, timing, rate, and/or other similar characteristics of the debonding repair device 400. The sensors 438 can be located at the protrusions 428 and/or along the vacuum support tool 412. In some embodiments, the sensors 438 can be positioned on the vacuum support tool 412 to measure the amount of force being applied to the bonded structure 402 to prevent any damage to the bonded structure 402.

Thus, in some embodiments, the debonding repair device 400 can be a combination of the debonding device 100, 200 shown in FIGS. 1A and 3 utilizing the fluid dispersion and temperature shock methods mentioned above. In some embodiments, the debonding repair device 400 can be a combination of the debonding devise 100, 300 shown in FIGS. 1A and 5 utilizing the fluid dispersion and shear force methods mentioned above. In some embodiments, the debonding repair device 400 can be a combination of the debonding devise 200, 300 shown in FIGS. 3 and 5 utilizing the temperature shock and shear force methods mentioned above. In some embodiments, debonding repair device 400 can be a combination of the debonding device 100, 200, 300 shown in FIGS. 1A, 3, and 5 utilizing the fluid dispersion, temperature shock, and shear force methods mentioned above.

In some embodiments, the debonding repair device 400 can further include an enclosure 440 that can be similar or identical to the enclosures 140 and/or 240 in FIGS. 2 and 4. The enclosure 440 can be pressed to a surface of carrier 404 and surrounds and forms a seal around at least one of at least one of the first semiconductor element 406, the vacuum support tool 412, and the fluid system 420. In some embodiments, the enclosure 140 can remove dispensed fluid within the enclosure 440 via a vacuum port 442 located on a surface of the enclosure 440. Additionally or alternatively, the enclosure 440 can protect other adjacent semiconductor elements from being affected by the fluid and/or fluid system 420. In some embodiments, an inert gas stored in in storage tank 446 can be dispensed into the enclosure 440 to remove air from the volume surrounding the first semiconductor element 406 to prevent condensation if the temperature adjustment pad 444 is colder than a dew point of an ambient environment of the debonding repair device 400.

### Examples of Direct Bonding Methods and Directly Bonded Structures

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

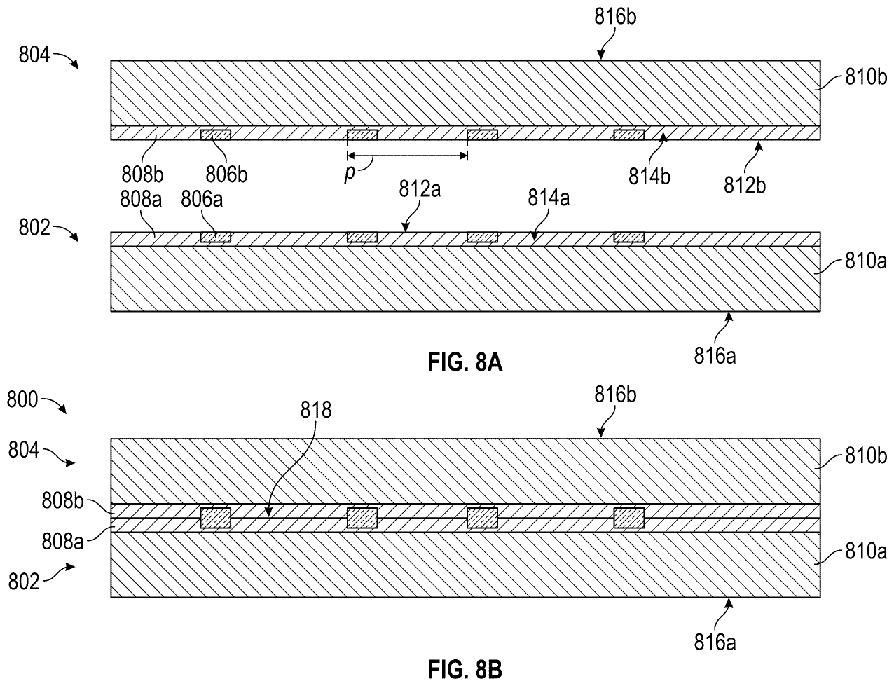

FIGS. 8A and 8B schematically illustrate cross-sectional side views of first and second elements 802, 804 prior to and after, respectively, a process for forming a directly bonded structure, and more particularly a hybrid bonded structure, according to some embodiments. In FIG. 8B, a bonded structure 800 comprises the first and second elements 802 and 804 that are directly bonded to one another at a bond interface 818 without an intervening adhesive. Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b, and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° ° C. to 100 ppm/° C., 5 ppm/° ° C. to 40 ppm/° C., 10 ppm/° ° C. to 100 ppm/° C., or 10 ppm/° ° C. to 40 ppm/° ° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO3) or lithium niobate (LiNbO3), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 8A prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 111 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

### Terminology

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

Several illustrative examples of debonding repair devices and related systems and methods have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps may be arranged or performed differently than described and components, elements, features, acts, or steps may be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed invention. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages and features of the inventions have been described herein. Not all, or any such advantages are necessarily achieved in accordance with any particular example of the inventions disclosed herein. No aspects of this disclosure are essential or indispensable. In many examples, the devices, systems, and methods may be configured differently than illustrated in the figures. or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

1.-111. (canceled)

112. A method of repairing a bonded structure, the method comprising:
debonding from a carrier a first semiconductor element that is directly bonded to a bonding site of the carrier;
cleaning the bonding site of the carrier; and
bonding a second semiconductor element to the bonding site of the carrier.

113. The method of claim 112, wherein the bonding comprises directly bonding the second semiconductor element to the bonding site of the carrier.

114. The method of claim 112, further comprising reducing a dielectric bond energy via a surface modification of the first semiconductor element and the carrier.

115. The method of claim 112, wherein the debonding a first semiconductor element from the carrier comprises delivering a fluid from one or more nozzles to a bonding interface between the first semiconductor element and the carrier.

116. The method of claim 115, wherein delivering the fluid comprises delivering the fluid from a vacuum support tool, wherein the vacuum support tool further comprises protrusions extending from the vacuum support tool surrounds one or more edges of the first semiconductor element.

117. The method of claim 116, wherein the one or more nozzles are disposed within the protrusions.

118. The method of claim 112, wherein the debonding a first semiconductor element from the carrier comprises:
contacting a temperature adjustment pad disposed on a lower surface of a vacuum support tool to a top surface of the first semiconductor element;
wherein the temperature adjustment pad applies a thermal shock to the first semiconductor element to weaken the bond between the first semiconductor element and the carrier.

119. A method of repairing a bonded structure, the method comprising:
bonding a first semiconductor element to a carrier at a bonding site of the carrier to form a bonded structure;
detecting a bonding defect in the bonded structure after bonding the first semiconductor element to the carrier;
debonding the first semiconductor element from the bonding site of the carrier; and
bonding a second semiconductor element to the bonding site of the carrier.

120. The method of claim 119, wherein the bonding comprises directly bonding the second semiconductor element to the bonding site of the carrier.

121. The method of claim 119, further comprising reducing the dielectric bond energy via a surface modification of the first semiconductor element and the carrier.

122. The method of claim 119, wherein the debonding a first semiconductor element from the carrier comprises positioning one or more protrusions extending from a vacuum support tool, the one or more protrusions surrounding one or more edges of the first semiconductor element and apply a shear force on the first semiconductor element.

123. The method of claim 119, further comprising etching at least one of an edge of the first semiconductor element and at least a portion of a bonding dielectric bonding dielectric layer of the carrier below the etched edge of the first semiconductor element.

124. The method of claim 119, further comprising removing the first semiconductor element by applying an upward vacuum force to a top surface of the first semiconductor element.

125. A method of repairing a bonded structure, the method comprising:
debonding from a carrier a first semiconductor element that is directly bonded to a bonding site of a carrier;
bonding a second semiconductor element to the bonding site of the carrier; and
annealing the second semiconductor element and the carrier.

126. The method of claim 125, wherein the bonding comprises directly bonding the second semiconductor element and the carrier.

127. The method of claim 125, further comprising reducing a dielectric bond energy via a surface modification of the first semiconductor element and the carrier.

128. The method of claim 125, wherein the debonding a first semiconductor element from the carrier comprises delivering a fluid from one or more nozzles a bonding interface between the first semiconductor element and the carrier to reduce the bond energy, wherein delivering the fluid comprises delivering the fluid from a vacuum support tool, wherein the vacuum support tool further comprises protrusions extending from the vacuum support tool and surrounding one or more edges of the first semiconductor element, and wherein the nozzles are disposed within the protrusions.

129. The method of claim 125, wherein the debonding a first semiconductor element from the carrier comprises placing a temperature adjustment pad disposed on a lower surface of a vacuum support tool in contact with a top surface of the first semiconductor element;
wherein the temperature adjustment pad applies a thermal shock to the first semiconductor element to weaken the bond between the first semiconductor element and the carrier; and
wherein the thermal shock breaks the bond between the first semiconductor element and the carrier.

130. The method of claim 125, further comprising etching at least one of an edge of the first semiconductor element and at least a portion of a bonding dielectric bonding dielectric layer of the carrier below the etched edge of the first semiconductor element, wherein the etching comprises sloped profile or a straight profile.

131. The method of claim 125, further comprising attaching a vacuum chuck to the carrier and a vacuum support tool to the first semiconductor element; and
removing the first semiconductor element by applying an upward vacuum force to a top surface of the first semiconductor element.
